(19) United States
(12) Patent Application Publication
(10) Pub. No.: US 2024/0182291 A1
(43) Pub. Date: Jun. 6, 2024

(54) FAILURE DETECTION METHOD, FAILURE DETECTION SYSTEM, AND ELECTROSPRAY ION SOURCE

(71) Applicant: HITACHI, LTD., Tokyo (JP)

(72) Inventors: Shun Kumano, Tokyo (JP); Hideki Hasegawa, Tokyo (JP); Masuyuki Suguyama, Tokyo (JP)

(21) Appl. No.: 18/437,338

(22) Filed: Feb. 9, 2024

Related U.S. Application Data
(63) Continuation of application No. 17/694,083, filed on Mar. 14, 2022, now Pat. No. 11,932,531.
(60) Provisional application No. 63/299,081, filed on Jan. 13, 2022.

(30) Foreign Application Priority Data
Feb. 28, 2023 (JP) 2023-030220

(51) Int. Cl. B81B 3/00; B81C 1/00; G02B 7/02; H04N 23/54; H04N 23/68

(52) U.S. Cl. CPC B81B 3/0072; B81C 1/00666; H04N 23/54; H04N 23/687; B81B 2203/0118; B81B 2203/019; B81B 2203/0307; B81C 2201/0105; B81C 2201/0178; G02B 7/021

(57) ABSTRACT

The present invention is characterized by involving a light source irradiating the inside of an ion source with light, a camera acquiring intensity as information of scattered light by droplets generated by electrospraying, and a processing device storing, in a storage unit, determination reference information indicating a relationship between a parameter of a channel system of a liquid chromatography device and the intensity, in which the processing device executes: acquiring the intensity from the camera; comparing the acquired intensity with the determination reference information; and determining a failure of a channel system in the liquid chromatography device by detecting a change in the scattered light relative to a value of the determination reference information based on the acquired intensity by comparing the acquired intensity with the determination reference information.

### CROSS-REFERENCE TO RELATED APPLICATIONS

This application claims benefit of foreign priority to Japanese Patent Application No. 2023-030220, filed Feb. 28, 2023. The entire contents of that application are also incorporated by reference.

### FIELD OF THE INVENTION

The present invention relates to technologies of a failure detection method, a failure detection system, and an electrospray ion source.

### BACKGROUND OF THE INVENTION

There are a wide range of applications of the mass spectrometer, such as measurement of soil and air pollution, pesticide testing in food, diagnosis based on blood metabolites, urine drug testing, and explosive detection. In general, a mass spectrometer is often used in combination with a pretreatment unit and a separation unit for gas chromatography, liquid chromatography, solid phase extraction, and the like. In particular, liquid chromatography devices are frequently used. Such a liquid chromatography device is generally used together with an electrospray ion source of a mass spectrometer. Although the measurement throughput of the mass spectrometer is high, liquid chromatography takes time to separate on the column. Therefore, this causes a decrease in throughput of the entire liquid chromatography mass spectrometer that is a combination of the liquid chromatography device and the mass spectrometer.

A solution for solving such a decrease in throughput is parallelization. The throughput of the liquid chromatography mass spectrometer can be improved by preparing a plurality of channel systems and parallelizing a plurality of columns. However, parallelizing the liquid chromatography means an increase in the number of components constituting a liquid feeding system such as a channel, a valve, and a pump. The liquid chromatography device performs mixing an organic solvent and an aqueous solvent, controlling the amount of liquid to be fed, and the like, thereby the amount of liquid to be fed and the mixing ratio deviate from accurate values when any part of a component does not work appropriately.

When a large number of components are present due to parallelization of the liquid feeding system, it is not realistic to monitor the situation by attaching sensors or the like to all the components. The failure of the channel system of the liquid chromatography device affects the ionization of the sample in the ion source in the mass spectrometer. As a result, the data output from the mass spectrometer could be an abnormal value. However, from the viewpoint of the user, even if the data of the mass spectrometer is an abnormal value, a user is not able to know where the abnormality has occurred in the entire liquid chromatography mass spectrometer. In addition, not only in the channel system, but also in a case where the electrode potential in the mass spectrometer becomes abnormal, the data could be an abnormal value.

Even if the channel system is parallelized, the solvent is finally fed to the electrospray ion source. Therefore, there is a possibility that the abnormality of the channel system can be determined by monitoring the state of the electrospray ion source. As a method for monitoring the state of the electrospray ion source, for example, JP 2004-534354 W discloses a method and a device for feedback controlling electrospray “with an optical system for monitoring and controlling the dynamic or static shape of a fluid exiting an electrospray nozzle” (see Abstract).

In addition, JP 2021-4814 A discloses an ion source abnormality detection device “that sprays a sample liquid containing a component to be analyzed into an ion source spray chamber using a spray means and detects an abnormality of an ion source that ionizes the component to be analyzed and a mass spectrometer using the same, the ion source abnormality detection device comprising: an irradiation means that irradiates the ion source spray chamber with light; an imaging means that captures an image of the inside of the ion source spray chamber; a captured image storage means that stores a captured image including a spray tip portion of the spray means captured by the imaging means; a spray state determination condition setting means that sets and stores in advance a setting value of an intensity gradation value of at least one or more determination pixels in the captured image; and a spray abnormality detection means that detects an abnormality of a spray state using the intensity gradation value of the determination pixel in the stored captured image and the setting value”, and a mass spectrometer using the same (see Abstract).

### SUMMARY OF THE INVENTION

In the liquid chromatograph mass spectrometer in which the channel system is complicated by parallelizing the channel systems, it is difficult to detect occurrence of an abnormality and where the abnormality has occurred. In addition, the techniques described in JP 2004-534354 W and JP 2021-4814 A are techniques for monitoring whether the state of the electrospray ion source itself is normal or abnormal, and there is a room for improvement in the case of determining also the state of the channel system.

The present invention has been made in view of such a background, and an object of the present invention is to detect a failure of a liquid chromatography device by a simple method.

In order to solve the above problem, the present invention involves a light source that irradiates an inside of an electrospray ion source with light, a scattered light information acquisition device that acquires scattered light information that is information of scattered light which is the light scattered by a droplet generated by electrospraying, and a processing device that stores, in a storage unit, determination reference information indicating a relationship between a parameter of a channel system of a liquid chromatography device in a normal state and the scattered light information, in which the processing device executes: acquiring the scattered light information from the scattered light information acquisition device; comparing the acquired scattered light information with the determination reference information; and determining, by the comparing, a failure of a channel system in the liquid chromatography device by detecting a change in the scattered light based on the acquired scattered light information with respect to a value of the determination reference information.

Other solutions will be appropriately described in the embodiments.

According to the present invention, a failure of a liquid chromatography device can be detected by a simple method.

### BRIEF DESCRIPTION OF THE DRAWINGS

FIG. 1 is a schematic view of a measurement system for measuring a spray state of an electrospray ion source.

FIG. 2 is a diagram illustrating a configuration of an abnormality detection system used in the present embodiment.

FIG. 3 is a diagram illustrating a configuration of a processing device according to the present embodiment.

FIG. 4A is an image obtained by forming a laser of 520 nm into a sheet with a lens, irradiating an ion source with the laser, and capturing scattered light R.

FIG. 4B is a diagram illustrating an intensity distribution in a case where the flow rate is 0.2 mL/min;

FIG. 4C is a diagram illustrating an intensity distribution in a case where the flow rate is 0.4 mL/min.

FIG. 4D is a diagram (part 1) illustrating the total

FIG. 5 is a schematic diagram illustrating a relationship between a flow rate and intensity.

FIG. 6A is a view showing an image of scattered light R by an ion source when a mixing ratio of methanol and an aqueous solvent is changed.

FIG. 6B is a diagram (part 2) illustrating the total intensity.

FIG. 7 is a diagram showing a relationship between a solvent mixing ratio of an aqueous solvent and an organic solvent, that is a ratio of water to the organic solvent, and intensity.

FIG. 8A is a diagram showing a temporal change of a ratio of methanol to an aqueous solvent when the ratio is linearly changed.

FIG. 8B is a diagram showing an example of a temporal change in intensity when a ratio of methanol to an aqueous solvent is temporally changed.

FIG. 9 is a schematic diagram of temporal changes in intensity in a normal state and an abnormal state.

FIG. 10A is a view illustrating an image in a case where air bubbles are not contained in the ion source and an image in a case where air bubbles are contained in the ion source.

FIG. 10B is a diagram (part 3) illustrating the total

FIG. 10C is a view illustrating an intensity change in a state in which air bubbles are not contained in the ion source.

FIG. 10D is a view illustrating an intensity change in a case where air bubbles are contained in the ion source.

FIG. 11A is an image of scattered light R when the flow rate of the auxiliary gas at 300° C. is changed to 5, 10, and 15 L/min.

FIG. 11B is a diagram (part 4) illustrating the total intensity.

FIG. 12 is a flowchart showing a processing procedure of a normal detection method by the processing device according to the first embodiment.

FIG. 13A is a view (part 1) illustrating a structure of an ion source according to a second embodiment.

FIG. 13B is a view (part 2) illustrating a structure of an ion source according to the second embodiment.

FIG. 14A is a view (part 1) illustrating a case where a light source device is installed in a light source installation portion of a housing and a camera is installed in front of a transparent plate.

FIG. 14B is a view (part 2) illustrating a case where a light source device is installed in a light source installation portion of a housing and a camera is installed in front of a transparent plate.

FIG. 15A is a view (part 1) illustrating a modification of the second embodiment.

FIG. 15B is a view (part 2) illustrating a modification of the second embodiment.

### DESCRIPTION OF THE PREFERRED EMBODIMENTS

Hereinafter, modes for carrying out the present invention (referred to as “embodiments”) will be described with reference to the accompanying drawings. Note that, in the present embodiment, specific examples conforming to the principle of the present invention are illustrated, but these are for understanding the present invention, and are not used to interpret the present invention in a limited manner. Modifications obtained by combining or replacing the following embodiments with known techniques are also included in the scope of the present invention. In all the drawings for describing the embodiments, components having the same function are denoted by the same reference numerals, and the repeated description thereof will be omitted.

### First Embodiment

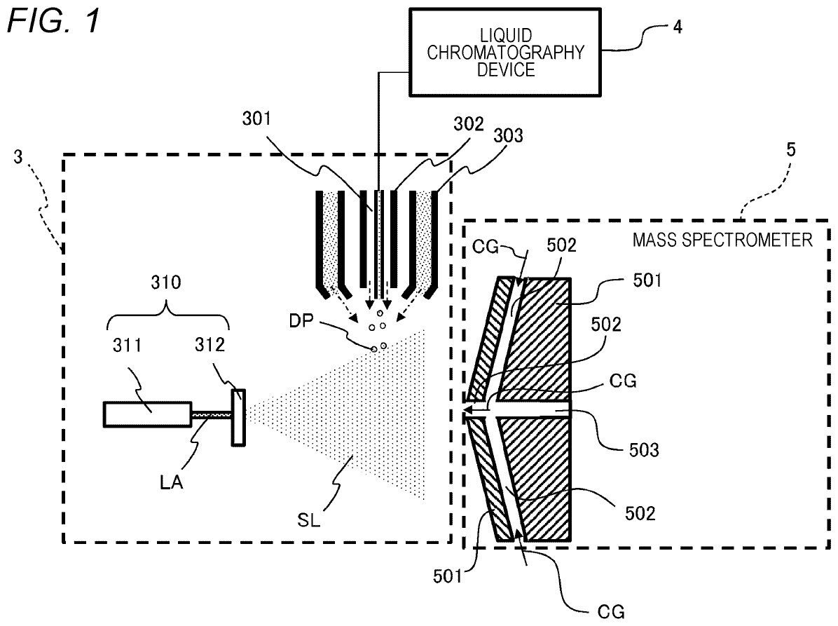

First, a first embodiment of the present invention will be described with reference to FIGS. 1 to 10.

### <Measurement System>

FIG. 1 is a schematic view of a measurement system for measuring a spray state of an electrospray ion source. In the present embodiment, the electrospray ion source is referred to as an ion source 3.

The ion source 3 includes a capillary 301, a nebulizer pipe 302, and an auxiliary gas pipe 303. Furthermore, the ion source 3 includes a light source 311 and a lens 312.

The capillary 301 allows a solvent to be analyzed by a mass spectrometer 5 to flow from a liquid chromatography device 4 into an ion source 3, and the solvent to be sprayed into the ion source 3. The nebulizer pipe 302 introduces a nebulizer gas (broken line arrow) for forming the nebulized droplet DP into a further micronized droplet DP into the ion source 3. The auxiliary gas pipe 303 is a pipe for introducing a high-temperature auxiliary gas (dashed-dotted line arrow) that promotes vaporization of the droplets DP.

A high voltage of about 4 kV is applied to the capillary 301. As a result, the droplet DP sprayed from the capillary 301 is charged. The charged droplet DP becomes a droplet DP having a smaller diameter while splitting after spraying. Finally, the molecules of the ionized droplet DP jump out of the droplet DP as ions (electrospray).

The ions pass through the pores 503 of the mass spectrometer 5 and are introduced into a mass separation unit (not illustrated) of the mass spectrometer 5. A counter plate 501 exists close to the ion source 3 in the mass spectrometer 5. The counter gas CG flows from the counter gas pores 502 of the counter plate 501 toward the ion source 3.

In the ion source 3, not all of the droplets DP are completely vaporized, and most of the droplets DP exist as the droplets DP. When the droplets DP are introduced into the mass spectrometer 5 as they are, the inside of the mass spectrometer 5 is contaminated. To prevent the contamination, the counter gas CG is injected toward the ion source 3 side so that the droplets DP are prevented from entering the mass spectrometer 5.

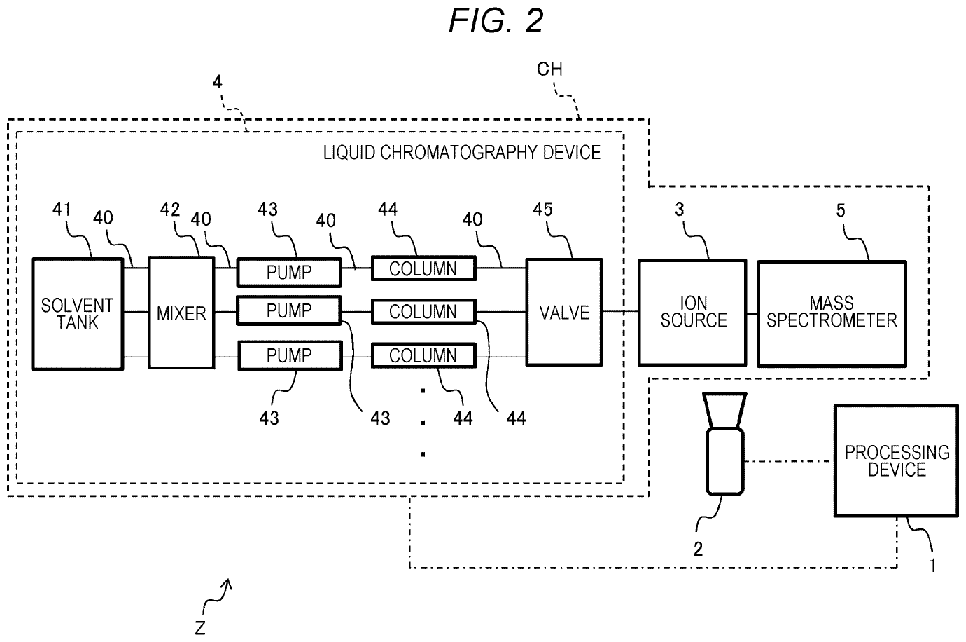

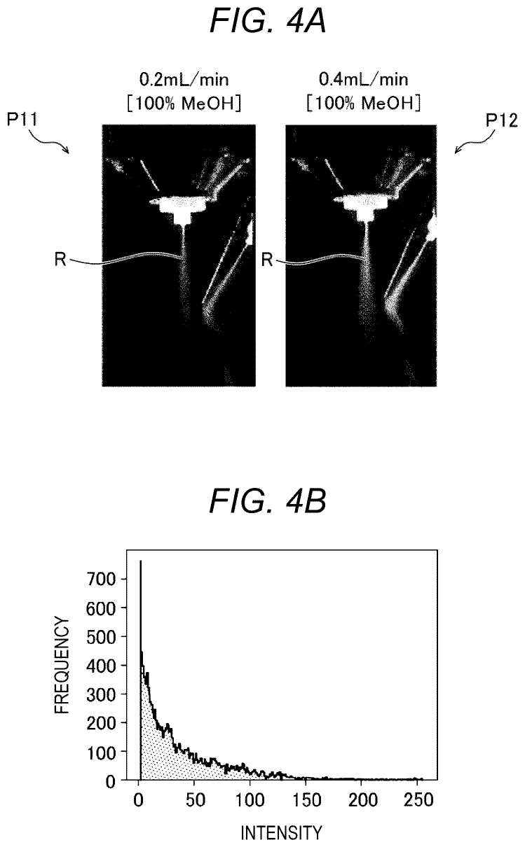

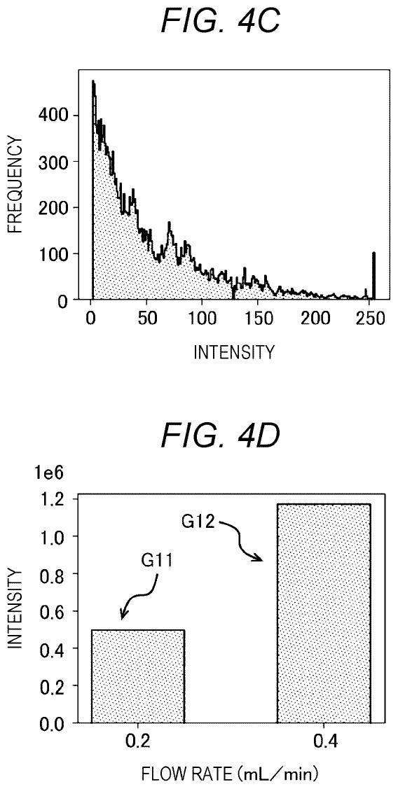

The light source 311 irradiates the inside of the ion source 3 with light. Specifically, in the present embodiment, a laser LA which is light is output from the light source 311 in order to visualize the distribution of the droplets DP. The output laser LA is made into a sheet shape by the lens 312 (laser sheet SL (light)). Note that the light source 311 and the lens 312 are collectively referred to as a light source device 310 as appropriate. Then, the micronized droplet DP is irradiated with the laser sheet SL having a thickness of about several mm. By irradiating the droplet DP with the laser sheet SL, scattered light R (see FIG. 4A and the like) is generated. In the present embodiment, the camera 2 (see FIG. 2) is installed in a direction orthogonal to the sheet surface of FIG. 1, and the scattered light R is captured by the camera 2, so that the intensity (more precisely, intensity information) of the scattered light R, which is scattered light information, is acquired. Hereinafter, the intensity of the scattered light R is simply referred to as intensity. The intensity is information of scattered light R scattered by a laser LA (laser sheet SL) by the droplet DP generated by electrospraying. The intensity is acquired as brightness of an image captured by the camera 2.

### <Failure Detection System Z>

FIG. 2 is a diagram illustrating a configuration of a failure detection system Z used in the present embodiment. In FIG. 2, a line indicated by a solid line indicates a path of a solvent, and a dashed-dotted line indicates a path of an electric signal.

In the failure detection system Z, the liquid chromatography mass spectrometer CH is provided with the camera 2 as a scattered light information acquisition device for acquiring intensity and the processing device 1. The camera 2 and the processing device 1 may be always provided in the liquid chromatography mass spectrometer CH. Alternatively, a service person of a manufacturer may provide the camera 2 and the processing device 1 in the liquid chromatography mass spectrometer CH at the time of inspection of the liquid chromatography mass spectrometer CH.

The liquid chromatography mass spectrometer CH includes the liquid chromatography device 4, the ion source 3, and the mass spectrometer 5.

The liquid chromatography device 4 includes a solvent tank 41, a mixer 42, a pump 43, a plurality of columns 44, and a valve 45. The solvent tank 41, the mixer 42, the pump 43, the plurality of columns 44, and the valve 45 are connected by a channel 40 through which the solvent flows. The solvent tank 41, the mixer 42, the pump 43, the plurality of columns 44, the valve 45, and the channel 40 constitute the channel system.

The solvent tank 41 stores a plurality of solvents. When these solvents are fed by the pump 43, they are mixed by the mixer 42 and then fed to the respective columns 44. Then, the components of the mixed solvent are separated by the column 44 which is a separation column. The valve 45 selects the column 44 to be connected to the ion source 3. By switching the valve 45, liquid can be fed to the plurality of columns 44 by one pump 43. When the solvent fed from the column 44 selected by the valve 45 is introduced into the ion source 3 and ionized, ions generated as a result of the ionization are fed to the mass spectrometer 5.

For example, the aqueous solvent and the organic solvent may be stocked in separate bottles in the solvent tank 41. In this case, the pump 43 suctions both the aqueous solvent and the organic solvent. Then, the aqueous solvent and the organic solvent suctioned by the pump 43 are mixed by the mixer 42 provided in the channel 40 and then introduced into the column 44.

In this manner, the liquid chromatography device 4 is connected to the capillary 301 (see FIG. 1) of the ion source 3. As a result, the solvent is introduced from the liquid chromatography device 4 into the ion source 3. In the present embodiment, a case where the solvents to be mixed in the liquid chromatography device 4 are an aqueous solvent and an organic solvent will be described, but the solvents to be mixed is not limited thereto. In the present embodiment, it is assumed that a plurality of solvents are mixed, but a single solvent may be fed to the column 44. In this case, the mixer 42 may be omitted.

In the present embodiment, the camera 2 captures an image of scattered light R (see FIG. 4A and the like) generated when the droplet DP (see FIG. 1) of the solvent is irradiated with the laser sheet SL (see FIG. 1) in the ion source 3. The captured image is transmitted to the processing device 1. The processing device 1 analyzes the transmitted image to determine the presence or absence of a failure in the channel system and an estimated failure part. The captured image includes intensity that is scattered light information. Therefore, the processing device 1 acquires intensity information by acquiring a captured image of the scattered light R from the camera 2.

The processing device 1 detects the occurrence of a failure in the channel system on the basis of an image captured by the camera 2 and can change a parameter of the channel system. The parameter of the channel system includes a solvent flow rate, a mixing ratio of solvents, or the like. However, the parameters of the channel system may be manually changed by a person. Hereinafter, the parameter of the channel system is simply referred to as a parameter. The solvent flow rate is the flow rate of the solvent flowing through the channel system. In the present embodiment, the mixing ratio refers to a mixing ratio of the solvents.

The rate limiting of the analysis throughput in the liquid chromatography mass spectrometer CH is mainly determined by the separation time in the column 44 of the liquid chromatography device 4. Therefore, in order to improve the throughput, it is conceivable to parallelize the flow of the solvent by setting a plurality of columns 44. As shown in FIG. 2, in the liquid chromatography device 4, a plurality of columns 44 are installed (a plurality of separation columns), and a valve 45 is installed at a subsequent stage thereof. An ion source 3 is connected to the valve 45. That is, the channel systems from the pump 43 to the column 44 are parallelized, and the parallelized channel systems are integrated in the ion source 3. In order to cause a solvent to flow through the column 44, the pump 43 is connected to each of the columns 44, and a solvent tank 41 is connected to a front stage of the pump 43.

In the example shown in FIG. 2, the pump 43 is provided in a one-to-one correspondence with the column 44, but the pump 43 does not necessarily have to be in a one-to-one correspondence with the column 44. In addition, for example, when the aqueous solvent and the organic solvent flow in the column 44, the solvent tank 41 of the aqueous solvent and the solvent tank 41 of the organic solvent are provided as the solvent tank 41. The pump 43 may be connected to each of the solvent tank 41 of the aqueous solvent and the solvent tank 41 of the organic solvent. That is, two pumps 43 may be connected to one column 44: the pump 43 provided in the solvent tank 41 for the aqueous solvent and the pump 43 provided in the solvent tank 41 for the organic solvent.

Although not illustrated in the example illustrated in FIG. 2, an injection valve for introducing a sample is also disposed in the channel system. Since the plurality of valves 45 and the plurality of pumps 43 are provided in this manner, the channel system is complicated. This increases the probability of failure occurrence during operation of the liquid chromatography device 4. On the other hand, since there are many components constituting the channel system, it is not easy to monitor the states of all the components.

As described above, the solvent having passed through the column 44 is introduced into one ion source 3. Therefore, even when a failure occurs in the channel system, the failure is detected by monitoring the ion source 3.

When the amount of ions varies due to an error in the channel system, it may be detected by the mass spectrometer 5. However, in a case where the fluctuation in the ion amount is used as an index, a failure of the mass spectrometer 5 is highly likely a factor of the fluctuation. Therefore, it is not appropriate to use the fluctuation in the amount of ions detected by the mass spectrometer 5 for monitoring the channel system.

In the present embodiment, the processing device 1 monitors the state of the droplet DP sprayed from the ion source 3 to detect a failure of the channel system. Specifically, the processing device 1 detects a failure in the channel system on the basis of scattered light R (see FIG. 4A and the like) emitted from the droplet DP.

As the failure of the channel system, for example, the following cases and the like is exemplified.
(Z1) A decrease in the flow rate of the solvent reaching the ion source 3 due to the leakage of the solvent and contamination of bubbles in the channel system.
(Z2) An increase or decrease in the solvent flow rate and a decrease in stability due to a failure of the pump 43.
(Z3) Abnormality of the mixing ratio of a plurality of kinds of solvents.
(Z4) Insufficient mixing due to malfunction of the mixer 42.
   These failures are reflected in the spray state of the droplet DP in the ion source 3.

In the present embodiment, the above-described failures are detected by observing the scattered light R (see FIG. 4A and the like).

### <Processing Device 1>

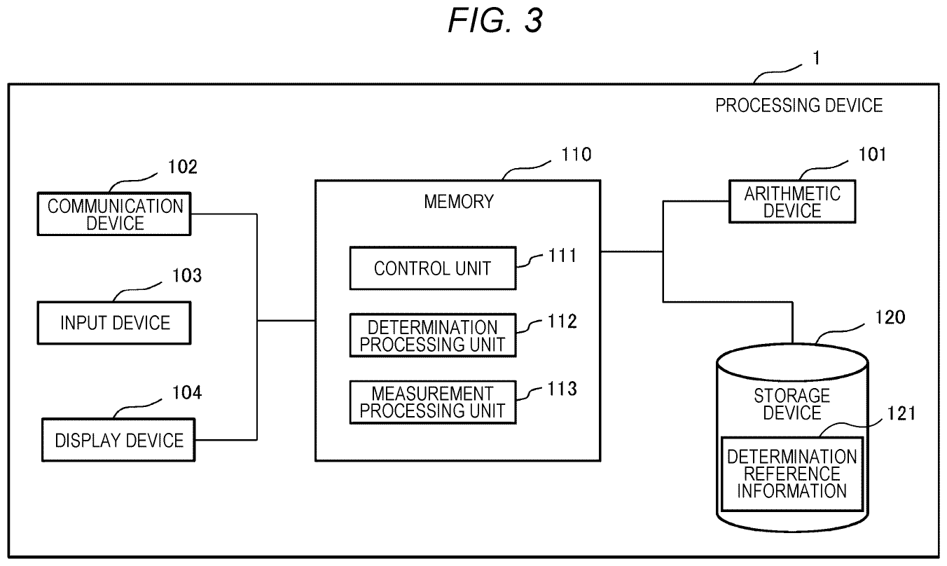

FIG. 3 is a diagram illustrating a configuration of the processing device 1 according to the present embodiment. FIG. 2 is referred to as appropriate.
The processing device 1 includes a memory 110, a storage device 120, an arithmetic device 101, a communication device 102, an input device 103 such as a keyboard and a mouse, and a display device 104 such as a display.
The storage device 120 includes a hard disk (HD), a solid state drive (SSD), and the like. The storage device 120 as the storage unit stores determination reference information 121. The determination reference information 121 stores information related to a relationship between a parameter of the channel system of the liquid chromatography device 4 in a normal state and the scattered light information. The normal state is a state where at least the liquid chromatography device 4 (channel system) has no failure. The failure detection of the channel system is performed by comparing the determination reference information 121 with the acquired intensity information. The parameter of the channel system includes a solvent flow rate, and a mixing ratio of solvents. Furthermore, the communication device 102 communicates with the camera 2.

Then, the program stored in the storage device 120 is loaded into the memory 110, and the loaded program is executed by the arithmetic device 101. As a result, the control unit 111, the determination processing unit 112, and the measurement processing unit 113 are embodied. The control unit 111 performs parameter control of the liquid chromatography device 4 (channel system). The determination processing unit 112 performs failure determination of the channel system from the image of the scattered light R (see FIG. 4A and the like) input from the camera 2.

The measurement processing unit 113, which is the scattered light information acquisition unit, receives an image captured by the camera 2 from the camera 2, and measures the intensity of the scattered light R from the image. As described above, the determination processing unit 112 determines the failure by detecting a change in the trend of the relationship between the parameter such as the solvent flow rate and the mixing ratio of the solvents, and the characteristic of the scattered light R.

Next, failure detection in the channel system will be described for each case with reference to FIGS. 4A to 11B. In the following description, FIGS. 1 to 3 will be referred to as appropriate.

### <Failure Determination of Solvent Flow Rate>

FIG. 4A is an image obtained by forming a laser LA of 520 nm into a sheet with the lens 312, irradiating the ion source 3 with the laser, and capturing the scattered light R. In FIG. 4A, the flow rate of the solvent introduced into the ion source 3 is 0.2 mL/min or 0.4 mL/min. An image P11 shown in FIG. 4A shows a case where the solvent flow rate is 0.2 mL/min, and an image P12 shows a case where the solvent flow rate is 0.4 mL/min. Further, the images P11 and P12 show a case where the solvent is 100% methanol.

FIG. 4B is a diagram illustrating an intensity distribution at a solvent flow rate of 0.2 mL/min (corresponding to image P11 in FIG. 4A). FIG. 4C is a diagram illustrating an intensity distribution at a solvent flow rate of 0.4 mL/min (corresponding to image P12 in FIG. 4A). In FIGS. 4B and 4C, the horizontal axis represents intensity, and the vertical axis represents frequency. In FIGS. 4B and 4C, the intensity is divided into “0” to “255”, and the histogram is drawn when the intensity is “2” or greater. The histogram is drawn with the intensity “2” or greater, because the intensity is “0” or “1” in most pixels, and adding the intensity “0” or “1” to the histogram makes the difference between the measurement conditions hardly visible in the graph.

FIG. 4D is a diagram illustrating the total intensity. In FIG. 4D, the horizontal axis represents the solvent flow rate (mL/min), and the vertical axis represents the intensity. In FIG. 4D, a graph G11 shows the total intensity at a solvent flow rate of 0.2 mL/min. In FIG. 4D, graph G12 is a graph showing the total intensity at a solvent flow rate of 0.4 mL/min.

The total intensity is calculated by the following equation on the basis of the intensity distributions in FIGS. 4B and 4C, and is the total intensity of the scattered light R derived from the droplet DP.

$$Total intensity = {\sum }_{Intensity} Intensity \times Frequency \qquad [ Formula 1 ]$$

In this equation, the frequency is the frequency of the intensity shown in FIGS. 4B and 4C.

As can be seen from FIGS. 4A and 4D, when the flow rate of the solvent to be introduced decreases, the intensity decreases. Conversely, even if the solvent is set to flow at 0.4 mL/min, the intensity decreases since the flow rate of the solvent substantially introduced into the ion source 3 is 0.2 mL/min due to leakage or the like. That is, when the intensity becomes equal to or less than a predetermined value under the situation of the solvent being expected to flow at 0.4 mL/min, the determination processing unit 112 of the processing device 1 determines that the leakage occurs in the channel system.

In the present embodiment, the relationship between the solvent flow rate and the intensity is set in advance as the determination reference information 121 (see FIG. 3). The determination reference information 121 may be created on the basis of a test, an experiment, and the like. The determination processing unit 112 determined that a failure has occurred in the channel by detecting a larger deviation between the acquired information (intensity) of the scattered light R and the relationship stored in the determination reference information 121.

However, the absolute value of the intensity may change depending on the machine difference of the ion source 3 and the liquid chromatography device 4 or the measurement environment. Therefore, in the present embodiment, when the failure of the channel system is examined, the parameter of the channel system is changed, and the trend of the change in intensity at that time is examined.

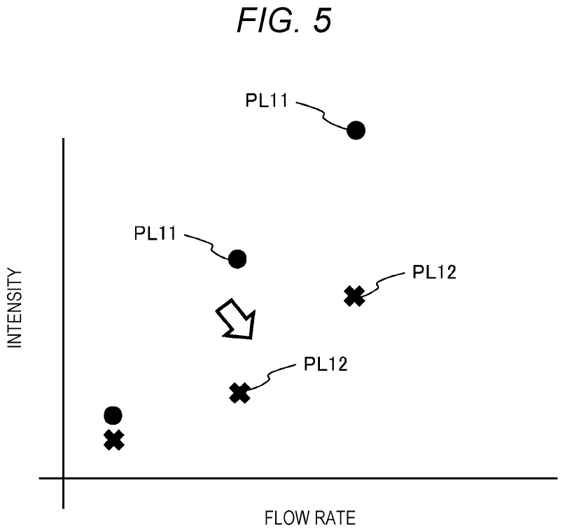

FIG. 5 is a schematic diagram illustrating a relationship between the solvent flow rate and the intensity. In the drawing of FIG. 5, the solvent flow rate is described as a flow rate.

For example, when the solvent flow rate is increased in a normal state, the intensity linearly increases as indicated by a reference sign PL11 in FIG. 5. Then, when a failure such as leakage occurs in the channel system, not only the absolute value of the intensity decreases as indicated by a reference sign PL12 in FIG. 5, but also a change in trend in which the relationship between the solvent flow rate and the intensity becomes nonlinear (open arrow in FIG. 5) is presumed. When a result as shown in FIG. 5 is detected, a possible failure of the channel system is as follows. Incidentally, data indicated by the reference sign PL11 is stored in the determination reference information 121 (see FIG. 3).

As described above, the determination reference information 121 stores information related to the relationship between the flow rate of the solvent flowing through the channel system and the intensity when no failure occurs in the channel system. In this way, it is possible to easily detect a failure of the channel system.
(A1) Leakage occurs in the channel system.
(A2) A liquid feeding abnormality has occurred in the pump 43, and liquid is not normally fed.
(A3) A failure has occurred in the solvent flow sensor, and the solvent flow rate has not been measured normally.
   In a case where the result as illustrated in FIG. 5 is obtained, the failure most likely to occur is A1.

As illustrated in this example, it is necessary to change parameters of the channel system in order to accurately detect a failure of the channel system. That is, it is desirable to be possible to set a monitoring mode for checking an absence of a failure in the channel system separately from the analysis mode for analyzing the component of the substance by the liquid chromatography mass spectrometer CH. In the monitoring mode, the measurement processing unit 113 of the processing device 1 changes parameters such as the solvent flow rate and the mixing ratio of the solvents, and acquires the characteristics of the scattered light R at that time. Then, as described above, the presence or absence of the failure is determined from the trend of the parameter and the characteristic of the scattered light R.

As shown in FIG. 5, the solvent flow rate, which is a parameter of the channel system, is changed by a plurality of values, and the intensity at each of the plurality of changed values is acquired. In this way, it is possible to compare in detail a change in intensity such as whether or not the intensity is linear, and thus, the accuracy of detection of the presence or absence of a failure is improved.

### <Determination of Mixing Ratio Abnormality (Failure of the Mixer 42)>

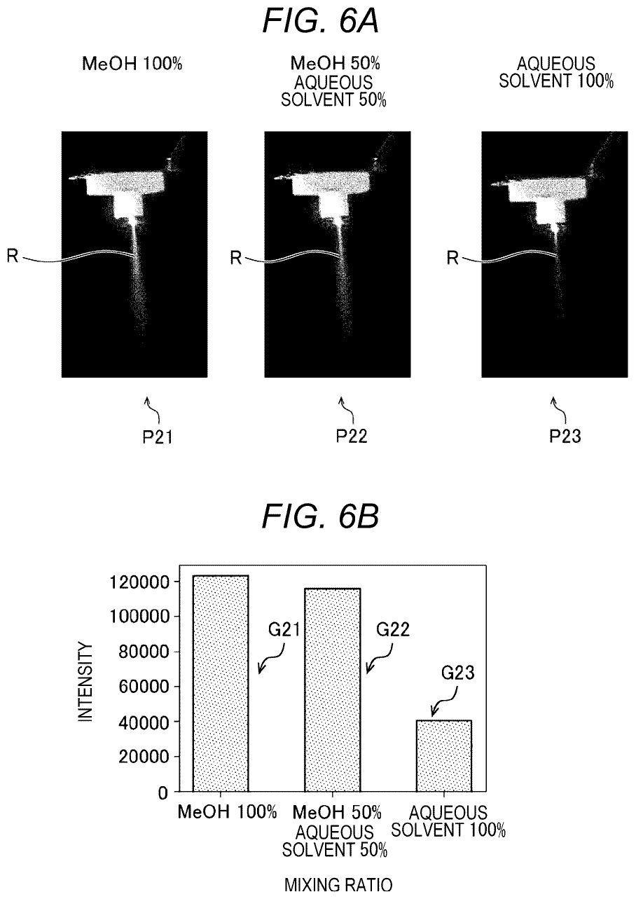

FIG. 6A is a view showing an image of scattered light R by the ion source 3 when a mixing ratio of methanol and an aqueous solvent is changed. FIG. 6B is a diagram illustrating the total intensity in FIG. 6A.
In the image shown in FIG. 6A, an image P21 shows a case of 100% methanol (MeOH), an image P22 shows a case of 50% methanol (MeOH) and 50% aqueous solvent, and an image P23 shows a case of 100% aqueous solvent. In addition, graphs G21 to G23 illustrated in FIG. 6B are diagrams illustrating the total intensity of the scattered light R illustrated in the images P21 to P23. A graph G21 indicates the total intensity of the scattered light R of the image P21 illustrated in FIG. 6A, and a graph G22 indicates the total intensity of the scattered light R of the image P22 illustrated in FIG. 6A. In addition, a graph G23 indicates the total intensity of the scattered light R of the image P23 illustrated in FIG. 6A. Note that the graphs G21 to G23 are generated by the same method as the graphs G11 and G12 illustrated in FIG. 4D. In addition, the vertical axis of the drawing illustrated in FIG. 6B represents intensity, and the horizontal axis represents a mixing ratio.

As indicated by the images P21 to P23 and the graphs G21 to G23, the intensity decreases as the mixing ratio of the aqueous solvent increases. When the laser LA of 520 nm is irradiated, the scattered light R is not generated and only diffraction occurs unless the particle size of the droplet DP becomes about 1 μm or less. When the ratio of the aqueous solvent is large in the mixed solvent, the particle size of the droplet DP increases, and the number of fine particles that emit the scattered light R decreases. Therefore, when the proportion of the aqueous solvent increases, the intensity decreases as shown in FIGS. 6A and 6B. That is, even if the liquid chromatography device 4 is set to feed liquid with 100% methanol, the aqueous solvent may be mixed due to a failure of the pump 43 or the like. In such a case, as illustrated in FIGS. 6A and 6B, the intensity is lower than expectation of the user.

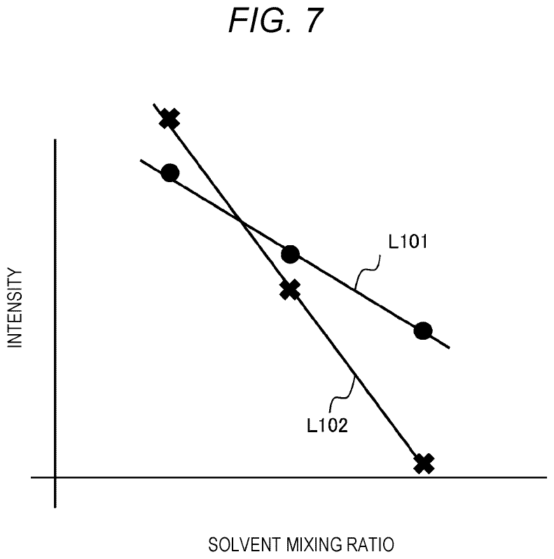

FIG. 7 is a diagram showing a relationship between a mixing ratio (solvent mixing ratio) of an aqueous solvent and an organic solvent, that is a ratio of water to the organic solvent, and intensity. In FIG. 7, the vertical axis represents intensity, and the horizontal axis represents a mixing ratio.

In FIG. 7, the mixing ratio refers to the mixing ratio of the aqueous solvent, and the proportion of the aqueous solvent increases toward the right in the drawing. In FIG. 7, a reference sign L101 denotes a relationship between the mixing ratio and the intensity in a normal state, and reference sign L102 denotes a relationship between the mixing ratio and the intensity in a failure state. As shown in FIG. 7, when the proportion of the aqueous solvent increases in the mixed solvent, the intensity of the scattered light R decreases. For example, when the setting and the actual state of the liquid chromatography mass spectrometer CH change in the mixing ratio of the aqueous solvent due to the failure of the pump 43, the relationship between the mixing ratio and the intensity changes as illustrated in FIG. 7. The determination processing unit 112 detects a failure in the channel system from a trend change in the relationship between the mixing ratio and the intensity as illustrated in FIG. 7. As described above, similarly to the solvent flow rate, it is desirable to use not only the absolute value of the intensity but also the trend of the relationship between the mixing ratio and the intensity. Incidentally, data indicated by the reference sign L101 is data stored in the determination reference information 121. As described above, the determination reference information 121 stores the relationship between the mixing ratio of the solvent in the channel system and the intensity when no failure occurs in the channel system. In this way, it is possible to easily detect a failure of the channel system.

When the relationship between the mixing ratio and the intensity as indicated by the reference sign L102 in FIG. 7 is obtained, it is considered that a failure has occurred in the mixer 42.

In the case of the liquid chromatography mass spectrometer CH, it is common to perform gradient analysis in which the mixing ratio of the solvent to be fed is continuously changed. For example, the mixing ratio is continuously changed from the mixing ratio of 95% aqueous solvent and 5% methanol to the mixing ratio of 100% methanol over 5 minutes. When a failure of the channel system is detected, that is, the solvent may be gradient also in the monitoring mode.

As shown in FIG. 7, the mixing ratio, which is a parameter of the channel system, is changed by a plurality of values, and the intensity at each changed value is acquired. In this way, it is possible to compare in detail a change in intensity according to the mixing ratio, and thus, it is possible to improve the accuracy of detection of the presence or absence of a failure.

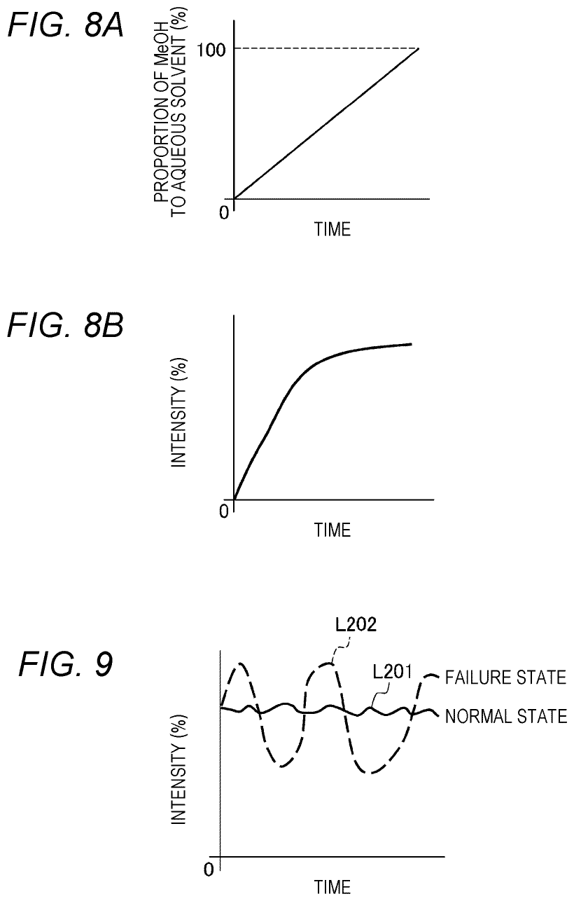

FIG. 8A is a diagram showing a temporal change of a ratio of methanol (MeOH) to an aqueous solvent when the ratio is linearly changed. FIG. 8B is a diagram showing an example of a temporal change in intensity when the ratio of methanol to the aqueous solvent is temporally changed as shown in FIG. 8A. In FIG. 8A, a continuous change in the scattered light R (see FIG. 6A and the like) when a mixing ratio of a plurality of solvents introduced into the ion source 3 is continuously changed is acquired. In addition, the vertical axis in FIG. 8B indicates the intensity, given that the intensity is 100% when the ratio of methanol (MeOH) to the aqueous solvent is 100%.

As shown in FIGS. 8A and 8B, in the case of 100% the aqueous solvent, the intensity is low, and as the amount of methanol increases, the droplet DP becomes finer, so that the intensity increases. This means that the mixing ratio, which is one of the parameters, is temporally changed, and the change in intensity at that time is examined. Even in this case, the presence or absence of a failure may be determined by comparing the trend of the intensity change with the data in the normal state stored in the determination reference information 121. By continuously changing the mixing ratio in this manner, it is possible to acquire a continuous change in intensity. In FIGS. 8A and 8B, the mixing ratio of the aqueous solvent and methanol is changed linearly as shown in FIG. 8A, but the mixing ratio is not necessarily linear. For example, a stepwise mixing ratio change that discontinuously changes the mixing ratio of the aqueous solvent and ethanol may be performed.

As described above, when a failure of the channel system is detected by a change in the mixing ratio, the mixing ratio may be changed in the monitoring mode so as to be compared with the normal state stored in the determination reference information 121.

### (Detection of Instability of Liquid Feeding)

FIG. 9 is a schematic diagram of temporal changes in intensity in a normal state and a failure state.
In FIG. 9, the horizontal axis represents time, and the vertical axis represents intensity (%). The intensity in FIG. 9 indicates the ratio of the intensity when the average value of the intensity in the normal state is defined as 100%.
When the parameter is constant, the intensity should be substantially constant with small variations (solid line L201 in FIG. 9). On the other hand, when a failure occurs in the pump 43 and the solvent flow rate is unstable, the intensity also varies (broken line L202 in FIG. 9). The variation in intensity corresponds to a variation in characteristics of the scattered light R (see FIG. 4A and the like). In such a case, as is clear from the comparison between the solid line L201 and the broken line L202 in FIG. 9, the average value of the intensity in the normal state (solid line L201) is substantially the same as the average value of the intensity in the failure state (broken line L202). In such a case, if the average value of the intensity is used as an index, there is a possibility that the user does not notice the liquid feeding failure.

With respect to the average value, the variation in intensity (the width of the vertical amplitude of the solid line L201 and the broken line L202) is obviously different between the normal state (the solid line L201) and the failure state (the broken line L202). Therefore, by using a variation in intensity as an index, such instability of liquid feeding can also be confirmed. The variation may be a standard deviation of intensity or a difference value between upper and lower limits.

Similarly, even if the setting of the mixing ratio of the solvent such as the aqueous solvent and the organic solvent is constant, it is possible to detect a variation in intensity when the mixture becomes unstable due to the liquid feeding abnormality.

### <Contamination of Air Bubbles>

If mixing of the solvent is insufficient due to malfunction of the mixer 42, degassing of the solvent itself is insufficient, or there is leakage, air bubbles may enter the solvent. When the air bubbles are directly introduced into the ion source 3, the amount of the solvent introduced into the ion source 3 substantially decreases at the moment when the air bubbles reach the ion source 3. As a result, the intensity decreases.

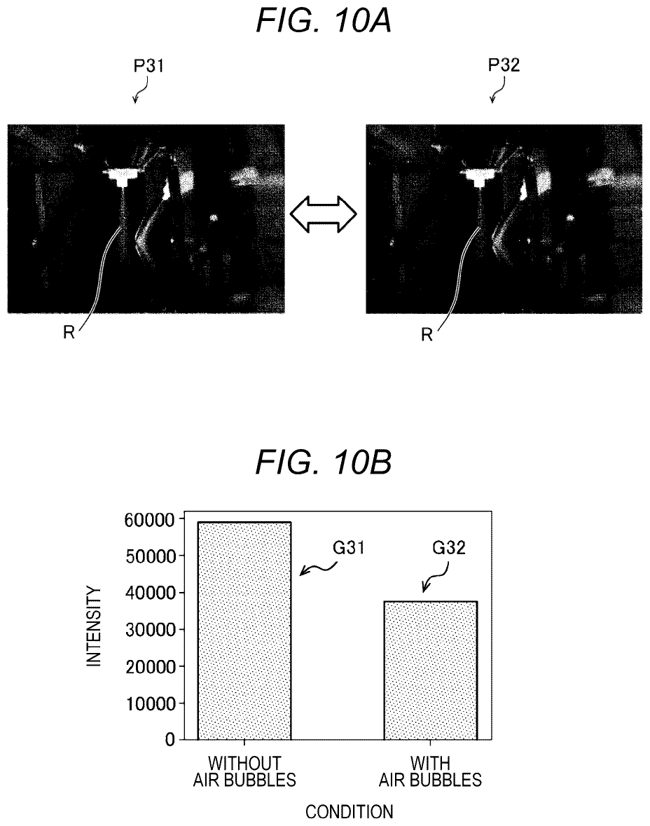

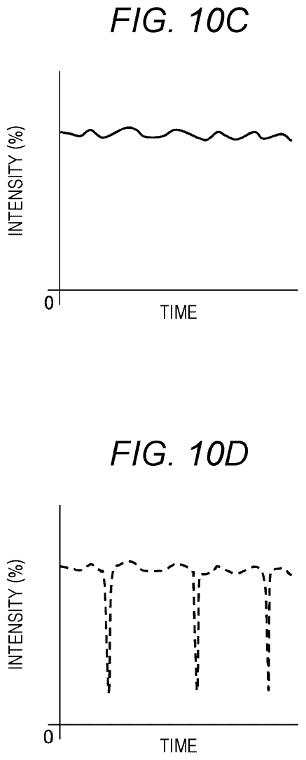

FIG. 10A is a view illustrating an image P31 in a case where air bubbles are not entered in the ion source 3 and an image P32 in a case where air bubbles are entered in the ion source 3.

FIG. 10B is a diagram illustrating the total intensity based on images P31 and P32 in FIG. 10A. In FIG. 10B, a graph G31 indicates the total intensity of the scattered light R in the image P31 illustrated in FIG. 10A, and a graph G32 indicates the total intensity of the scattered light R in the image P32 illustrated in FIG. 10A. The horizontal axis in FIG. 10B represents a condition indicating the presence or absence of air bubbles (with or without air bubbles). Since a method of generating the histogram illustrated in FIG. 10B is similar to the histogram of the total intensity illustrated in FIG. 4D, the description thereof is omitted.

When there is no air bubble in the solvent, an image like an image P31 in FIG. 10A is continuously acquired. However, when the solvent containing the bubbles is introduced into the ion source 3, the intensity of the scattered light R decreases as shown in an image P32 of FIG. 10A (see a graph G31 and a graph G32 of FIG. 10B). Since the diameter of the bubble is generally small, the decrease in intensity due to the introduction of the bubble is instantaneous. Therefore, the scattered light R changes from the state of the image P31 in FIG. 10A (the graph G31 in FIG. 10B) to the state of the image P32 in FIG. 10A (the graph G32 in FIG. 10B). Thereafter, the scattered light R returns to the state of the image of the image P31 in FIG. 10A (the graph G31 in FIG. 10B). As described above, since the diameters of the bubbles are generally small, the time in the state of FIG. 10B is instantaneous. However, in a case where a large number of bubbles are contained in the solvent, each time the bubbles reach the ion source 3, an image indicated by the image P32 in FIG. 10B is obtained, and thus, the image P31 and the image P32 in FIG. 10A alternately appear many times.

FIG. 10C is a diagram illustrating an intensity change in a state in which air bubbles are not contained in the ion source 3, and FIG. 10D is a diagram illustrating an intensity change in a case in which air bubbles are contained in the ion source 3. In FIGS. 10C and 10D, the horizontal axis represents time, and the vertical axis represents intensity (%). The intensity in FIGS. 10C and 10D indicates the ratio of the intensity when the average value of the intensity is 100% in a case where no air bubble is contained in the solvent.

As illustrated in FIG. 10C, when no air bubbles are contained in the ion source 3, the intensity remains substantially constant. In contrast to FIG. 10C, as illustrated in FIG. 10D, when air bubbles enter the ion source 3, the intensity decreases as described above (the state of the image P32 in FIG. 10A). However, since the bubbles are small, the intensity decreases for a short time. Therefore, as illustrated in FIG. 10D, the temporal change of the intensity in a short time causes the intensity to decrease in a short time.

In both the liquid feeding abnormality as shown in FIG. 9 and the mixture of the air bubbles as shown in FIGS. 10A to 10D, the variation in the temporal change of the intensity is greater than that in the normal state. Therefore, when the variation in the temporal change of the intensity is greater than that in the normal state, in other words, when the variation in the temporal change of the intensity is a predetermined value or more, it may be determined that the liquid feeding abnormality or the bubble mixture occurs. As described above, in FIGS. 9 to 11B, variations in the characteristics (variations in intensity) of the scattered light R (see FIG. 10A) generated from the droplet DP generated by electrospraying are evaluation indexes for failure determination. As a result, it is possible to determine a failure of the pump 43 and mixture of bubbles.

In addition, in a case where air bubbles are contaminated, the decrease in intensity is in the form of an instantaneous pulse as shown in FIG. 10D, whereas in a case where liquid feeding becomes unstable due to liquid feeding abnormality, the decrease in the intensity is not in the form of an instantaneous pulse as shown in FIG. 9. Therefore, the determination processing unit 112 determines that air bubbles are contaminated when the decrease in intensity is in the form of an instantaneous pulse, and determines that liquid feeding becomes unstable due to liquid feeding abnormality when the decrease in intensity is not in the form of an instantaneous pulse. Whether or not it is in the form of an instantaneous pulse may be determined whether or not the time during which the intensity is lower than the intensity change in the normal state is shorter than a predetermined time. If the time during which the intensity is lower than the intensity change in the normal state is shorter than the predetermined time, the determination processing unit 112 determines that the decrease in intensity is in the form of an instantaneous pulse. If the time during which the intensity is lower than the intensity change in the normal state is equal to or longer than the predetermined time, the determination processing unit 112 determines that the decrease in intensity is not in the form of an instantaneous pulse. As the predetermined time, a slightly longer time than the time estimated from the size of the bubble that can be generated may be set. In addition, the intensity change in the normal state to be compared may be an average value or a lower limit value of the intensity change in the normal state.

As described above, when the decrease in intensity occurs in a pulsed manner, the determination processing unit 112 determines that air bubbles are contaminated in the solvent flowing through the channel system. By performing such determination, it is possible to easily detect that air bubbles are contaminated in the solvent. On the other hand, as shown in FIG. 9, when the intensity decreases not in a pulsed manner, the determination processing unit 112 determines that liquid feeding is unstable due to a failure of the pump 43 that feeds the solvent flowing through the channel system. By performing such a determination, it is possible to easily detect that liquid feeding becomes unstable due to a failure of the pump 43.

In addition, temporal changes in intensity such as the solid line L201 in FIG. 9 and the intensity change illustrated in FIG. 10C are stored in the determination reference information 121 as information related to variations in information of scattered light when no failure occurs in the channel system. In this way, the determination processing unit 112 easily determines that the liquid feeding due to bubble contamination or failure of the pump 43 is unstable.

### <Monitoring Mode>

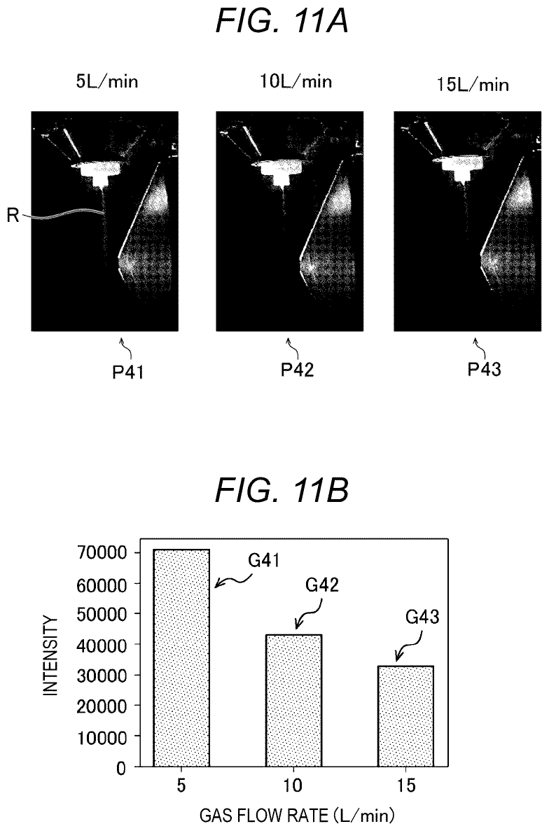

FIG. 11A is an image of scattered light R when the auxiliary gas flow rate at 300° C. is changed to 5, 10, and 15 L/min in a case where the solvent flow rate to the ion source 3 is as low as 0.03 mL/min. An image P41 in FIG. 11A is a case where the auxiliary gas flow rate is 5 L/min, an image P42 is a case where the auxiliary gas flow rate is 10 L/min, and an image P43 is a case where the auxiliary gas flow rate is 15 L/min. Note that the comparison images with respect to the images P41 to P43 illustrated in FIG. 11A are the images P11 and P12 illustrated in FIG. 4A. In the images P11 and P12 illustrated in FIG. 4A, the auxiliary gas flow rate is 5 L/min. That is, the image P11 of FIG. 4A shows a case where the auxiliary gas flow rate is 5 L/min and the solvent flow rate is 0.2 mL/min. An image P12 in FIG. 4A shows a case where the auxiliary gas flow rate is 5 L/min and the solvent flow rate is 0.4 mL/min. On the other hand, an image P41 of FIG. 11A shows a case where the auxiliary gas flow rate is 5 L/min and the solvent flow rate is 0.03 mL/min. As described above, when comparing the images P11 and P12 in FIG. 4A and the image P41 in FIG. 11A with the same auxiliary gas flow rate of 5 L/min, it is seen that the intensity decreases when the solvent flow rate is low.

FIG. 11B is a diagram illustrating the total intensity based on images P41 to P43 illustrated in FIG. 11A. A graph G41 illustrated in FIG. 11B indicates the total intensity based on the image P41 illustrated in FIG. 11A, and a graph G42 indicates the total intensity based on the image P42 illustrated in FIG. 11A. A graph G43 indicates the total intensity based on image P43 illustrated in FIG. 11A. Since the method of generating the histogram illustrated in FIG. 11B is similar to the method of generating the histogram illustrated in FIG. 4D, the description thereof will be omitted. The horizontal axis of the histogram in FIG. 11B indicates the auxiliary gas flow rate (L/min).

As illustrated in FIGS. 11A and 11B, as the auxiliary gas flow rate increases, vaporization of the droplets DP is promoted, so that the intensity decreases. In view of ionization efficiency, it is desirable to increase the auxiliary gas flow rate to promote vaporization. On the other hand, in a case where the purpose is to detect a failure of the channel system from the image information of the scattered light R, it is difficult to grasp a change in intensity without a certain level of intensity. In addition, when the temperature of the auxiliary gas is high, vaporization of the droplet DP is promoted, and the intensity of the scattered light R decreases. Therefore, in the monitoring mode, at least one of the auxiliary gas flow rate and the temperature of the auxiliary gas is lower than in the analysis mode. As a result, it is possible to prevent the droplet DP from being excessively vaporized. This is particularly important when the amount of the solvent introduced into the ion source 3 is small. This is because, when the amount of the solvent introduced into the ion source 3 is small, the amount of the droplet DP decreases and the intensity decreases. As described above, in the present embodiment, at least two modes of the analysis mode during ion measurement and the monitoring mode during state monitoring can be switched. In this way, the accuracy of failure determination is improved.

In the example shown in FIG. 2, a plurality of channel systems are controlled by the valve 45 and connected to the ion source 3. That is, in the example shown in FIG. 2, a plurality of channel systems are provided, and each channel system has a column 44. In such a case, the channel system to be monitored while controlling the valve 45 is changed. Then, the parameters are sequentially changed for each of the plurality of channel systems, and the droplet DP generated in the ion source 3 is irradiated with the laser sheet SL from the channel system in which the parameters have been changed. For example, when five columns 44 are connected, one column 44 and the ion source 3 are connected by the valve 45, and the measurement processing unit 113 acquires the image information of the scattered light R (see FIG. 4A and the like) while changing the parameters of the connected column 44. Then, when the determination of normality/failure by the determination processing unit 112 is completed, the control unit 111 connects another column 44 and the ion source 3. By repeating this process for five times, the state of the channel system connected to each column 44 may be checked. Note that the number of columns 44 is not limited to five.

In the present embodiment, the scattered light R by the droplet DP sprayed by the ion source 3 is generated using the light source 311, and the trend of the parameter and the trend of the temporal change are examined based on the information of the scattered light R. In this manner, the processing device 1 detects a failure in the channel system. The light source 311 is not necessarily the laser sheet SL. The spray region of the droplet DP is irradiated with the laser LA in a point manner, and information of the scattered light R at the irradiation point may be used as an index for failure detection. The information on the scattered light R at the irradiation point is, for example, intensity of the irradiation point. In addition, the device that acquires the information of the scattered light R does not need to be the camera 2. In the case of point irradiation with the laser LA or the like, a device that detects light intensity such as a photodiode (not illustrated) may be used as a device that acquires information of the scattered light R. Furthermore, as described above, there is a case where information of the scattered light R at a plurality of places is acquired by installing the plurality of cameras 2, but also in such a case, a plurality of photodiodes may be set without using the camera 2. Alternatively, the camera 2 and the photodiode may be installed in combination. However, irradiation can be performed in a wider range by using the laser sheet SL. As a result, the intensity acquisition range can be widened. In addition, by performing imaging by the camera 2, it is possible to acquire information of the scattered light R in a wide range. Furthermore, by capturing a video, it is possible to observe a temporal change of the scattered light R information. The video capturing is useful when the determination as illustrated in FIGS. 4 to 11D is performed. However, instead of video capturing, a still image may be captured at predetermined time intervals.

Further, since the laser sheet SL has a small thickness of several mm, the scattered light R generates only in the spray unit region, and the signal/noise ratio of data increases.

### <Flowchart>

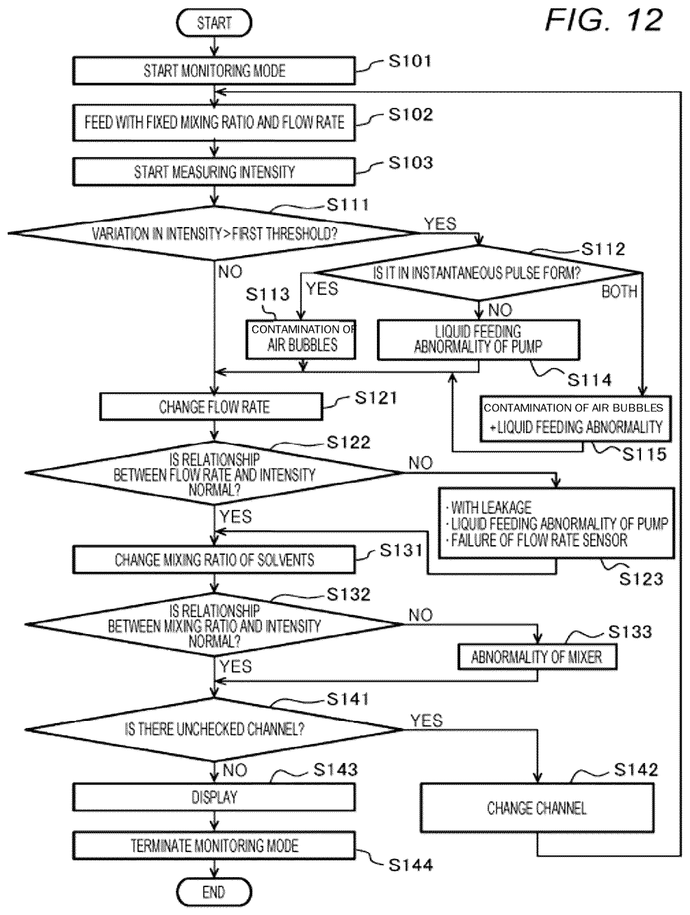

FIG. 12 is a flowchart illustrating a processing procedure of a failure detection method by the processing device 1 according to the first embodiment. FIGS. 2 and 3 are referred to as appropriate.
First, the control unit 111 starts the monitoring mode by switching the current mode to the monitoring mode (S101). As shown in FIGS. 11A to 11B, in the monitoring mode, at least one of the auxiliary gas flow rate and the temperature of the auxiliary gas is lowered by the control unit 111 than in the analysis mode.
Subsequently, the control unit 111 sends the solvent to the channel system with the mixing ratio and the solvent flow rate being fixed (S102). For example, liquid feeding is performed with 100% aqueous solvent or 100% organic solvent. In the drawing of FIG. 12, the solvent flow rate is described as a flow rate. The solvent flow rate may be set to any flow rate.

Then, when the scattered light R is captured by the camera 2, the measurement processing unit 113 starts measurement of intensity (S103). After step S103, the intensity may be continuously measured, or may be measured upon each determination. Step S103 is a scattered light information acquisition step in which the processing device 1 acquires intensity that is information of the scattered light R (see FIG. 10A) from the camera 2. In addition, after step S103, the measurement processing unit 113 continues to measure the intensity.

Next, the determination processing unit 112 determines whether the value of the variation in intensity in a certain period of time is greater than the first threshold (S111).

As a result of step S111, when the value of the variation in intensity in the certain time is greater than the first threshold value (S111: Yes), the determination processing unit 112 determines whether or not the decrease in intensity is in the form of an instantaneous pulse (S112). The determination as to whether or not the decrease in intensity is in the form of an instantaneous pulse is made on the basis of the contents described above.

As a result of step S112, when the decrease in intensity is in the form of an instantaneous pulse (S112: Yes), the determination processing unit 112 sets a flag indicating that air bubbles are contaminated in the channel system (air bubble contamination: S113). The process of step S111 “Yes”, step S112 “Yes”, and then step S113 is the process illustrated in FIGS. 10A to 10D. Then, the processing device 1 advances the processing to step S121.

When the determination is made as “Yes” in step S112, the contamination of the air bubbles shown in the case (Z1) is determined.

As a result of step S112, when the decrease in intensity is not in the form of an instantaneous pulse (S112: No), the determination processing unit 112 sets a flag indicating that the liquid feeding abnormality has occurred due to the failure of the pump 43 in the channel system (S114). The process of step S111 “Yes”, step S112 “No”, and then step S114 is the process illustrated in FIG. 9. After step S114, the processing device 1 advances the processing to step S121.

When it is determined as “No” in step S112, it is determined that the stability is deteriorated due to the failure of the pump 43 in the case (Z2).

Note that both the form of an instantaneous pulse and the other case may be detected in step S112 (S112: both). That is, an intensity change obtained by combining an intensity change indicated by the broken line L202 in FIG. 9 and an intensity change indicated in FIG. 10D may be detected. In such a case, the determination processing unit 112 sets a flag indicating that both the contamination of air bubbles and the liquid feeding abnormality occur (air bubble mixture+liquid feeding abnormality: S115). After step S115, the processing device 1 advances the processing to step S121.

As a result of step S111, when the value of the variation in intensity in a certain period is equal to or less than the first threshold (S111: No), control unit 111 changes the solvent flow rate (S121). The solvent flow rate is changed continuously or discretely. In step S121, the measurement processing unit 113 acquires the intensity when the flow rate of the solvent introduced into the ion source 3 changes. In this manner, the determination in step S123 described later is performed.

Then, the determination processing unit 112 determines whether the relationship between the solvent flow rate and the intensity is normal on the basis of the determination reference information 121 (S122). In a case where the intensity linearly increases as indicated by the reference sign PL11 illustrated in FIG. 5 in step S122, the determination processing unit 112 determines that it is normal (“Yes”) in step S122. When the absolute value of the intensity decreases as indicated by the reference sign PL12 in FIG. 5 and the relationship between the solvent flow rate and the intensity is nonlinear, the determination processing unit 112 determines failure (“No”) in step S122. Specifically, the determination processing unit 112 determines how far the measured relationship between the solvent flow rate and the intensity is from the normal relationship (reference sign PL11 in FIG. 5) measured in advance. How far the relationship between the measured solvent flow rate and the intensity is from the normal relationship measured in advance is determined by a sum of squares error between the measured relationship between the solvent flow rate and the intensity and the normal relationship measured in advance. More specifically, when the sum of squares error of the measured relationship between the solvent flow rate and the intensity in the normal state measured in advance is equal to or greater than a predetermined third threshold, the determination processing unit 112 determines in step S122 that the relationship between the solvent flow rate and the intensity is failure (“No”). The relationship between the intensity and the solvent flow rate indicated by the reference sign PL11 in FIG. 5 is held as the determination reference information 121.

As a result of step S122, when the relationship between the solvent flow rate and the intensity is abnormal (S122: No), the determination processing unit 112 sets a flag indicating that the following failures (A1) to (A3) occur (S123).
(A1) Leakage occurred in the solvent flow rate (with leakage).
(A2) A liquid feeding abnormality has occurred in the pump 43, and liquid is not normally fed.
(A3) A failure has occurred in the solvent flow sensor, and the solvent flow rate has not been measured normally.

When determination “No” is made in step S122, a decrease in the solvent flow rate due to the leakage in the case (Z1) and an increase or decrease (reduction) in the solvent flow rate due to a failure of the pump 43 in (Z2) are determined.

Note that the processing in steps S122 to S123 has been described with reference to FIGS. 4A to 5, and the items (A1) to (A3) have also been described in FIG. 5. After step S123, the processing device 1 advances the processing to step S131.

As a result of step S122, when the relationship between the solvent flow rate and the intensity is normal (S122: Yes), the control unit 111 changes the mixing ratio of the solvent by controlling the mixer 42 (S131). The mixing ratio is changed according to a plurality of preset mixing ratios. The mixing ratio may be changed continuously as shown in FIG. 8A or may be performed discretely. In step S131, the measurement processing unit 113 acquires the intensity when the mixing ratio of the plurality of solvents to be introduced into the ion source 3 changes. In this manner, the determination in step S133 described later is performed.

Then, the determination processing unit 112 determines whether the relationship between the mixing ratio and the intensity is normal (S132). For example, the determination processing unit 112 performs the determination in step S132 on the basis of the sum of squares error between the relationship of reference sign L101 in FIG. 7 set in advance as the determination reference information 121 and the relationship between the mixing ratio and the intensity changed in step S131. If the sum of squares error is equal to or greater than a preset fourth threshold value, the determination processing unit 112 determines failure (“No”) in step S132.

As a result of step S132, when it is determined that there is a failure (S132: No), the determination processing unit 112 sets a flag indicating that there is a failure in the mixer 42 (mixer abnormality: S133). Note that the processing in steps S132 “No” to S133 has been described with reference to FIGS. 6A to 8B. After step S133, the processing device 1 advances the processing to step S141.

When the determination is “No” in step S132, the abnormality of the mixing ratio of the plurality of kinds of solvents (Z3) and the insufficient mixing due to the malfunction of the mixer 42 (Z4) are determined.

As a result of step S132, when it is determined to be normal (S133: Yes), the determination processing unit 112 determines whether there is a channel system that has not been checked (S141).

As a result of step S141, when there is a channel system that has not been checked (S141: Yes), the control unit 111 operates the valve 35 to change the channel system to a channel system that has not been checked (S142).
Thereafter, the processing device 1 returns the processing to step S102, and performs the processing of step S102 and subsequent steps on the changed channel system.
As a result of step S141, when there is no unchecked channel system (S141: Yes), the display processing unit displays a determination result (a flagged event) on the display device 104 (S143), and then the processing device 1 terminates the monitoring mode (S144).

Note that steps S111, S112, S133, and S132 are comparison steps in which the processing device 1 compares the acquired intensity with the determination reference information 121. Steps S113, S114, S123, and S133 are determination steps in which the processing device 1 determines the failure of the channel system in the liquid chromatography device 4 by detecting the change in the acquired intensity with respect to the value of the determination reference information 121 in the comparison step.

According to the first embodiment, the failure of the liquid chromatography device is detected by a simple method. Further, according to the first embodiment, a defect (failure) of the channel system of the liquid chromatography device 4 is detected without requiring a large number of sensors.

In the first embodiment, the intensity of the scattered light R (see FIG. 4A and the like) generated from droplets generated by electrospraying is used as an evaluation index for failure determination. In this way, an evaluation index for failure determination of the channel system is obtained by a simple method.

In the processing shown in the flowchart of FIG. 12, the control unit 111 of the processing device 1 changes the parameters such as the solvent flow rate and the mixing ratio, but as described above, these parameters may be manually changed by a human.

As the characteristics of the scattered light R (see FIG. 4A and the like), information other than intensity may also be used. For example, an image captured by the camera 2 may be binarized, and then an area of a pixel having intensity derived from the scattered light R may be used for failure determination. The scattered light R also varies depending on the position to be observed. Therefore, by installing two or more cameras 2, characteristic information of the scattered light R is obtained for each observation position. That is, the angle of the scattered light R varies depending on the particle diameter of the droplet DP. Two or more cameras 2 are set, and the scattered light R is captured from different angles, whereby information regarding the particle diameter of the droplet DP is acquired. In addition, when the intensity information is used, an average value of intensity in a certain period of time may be used, or a variation thereof may be used.

### Second Embodiment

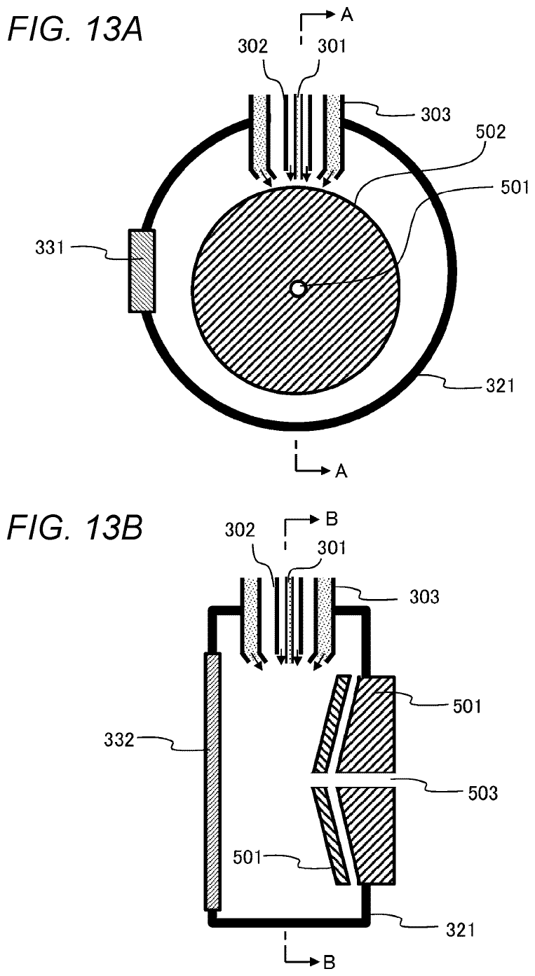

FIGS. 13 to 15 are diagrams illustrating a configuration of an ion source 3 according to the second embodiment. FIG. 1 is referred to as appropriate.
In the first embodiment, it is assumed that the light source 311 and the camera 2 are always installed in the ion source 3. Whether or not the light source 311 and the camera 2 are used is changed depending on whether the liquid chromatography mass spectrometer CH is in operation in an analysis mode in which normal operation is performed or whether the liquid chromatography mass spectrometer CH is in a monitoring mode in which the channel system is monitored. On the other hand, in the second embodiment, the light source 311 and the camera 2 are detachable from the ion source 3. This is because there is a possibility that installation of the light source 311 or the camera 2 in the ion source 3 is not preferable for ionization for the reasons described below. For example, since the auxiliary gas has a high temperature, when the light source 311 is installed in the vicinity of the spray port of the auxiliary gas, the light source 311 is exposed to the high-temperature auxiliary gas. In most cases, since the light source 311 cannot withstand high heat, the temperature of the auxiliary gas may not be sufficiently increased. When the temperature of the auxiliary gas is low, vaporization of the droplets DP is not promoted, and as a result, ionization efficiency is lowered. Accordingly, the sensitivity of the liquid chromatography mass spectrometer CH decreases.

Ions generated by the ion source 3 move due to a potential difference between the capillary 301 and the mass spectrometer 5. When the light source 311 is close to the spray port of the auxiliary gas, there is a possibility that the electric field in the vicinity of the spray port cannot be optimized. Further, when the substance is measured (when the analysis mode is performed) while the light source 311 is installed near the spray port of the auxiliary gas, the contamination problem of the light source 311 occurs. That is, when the light source 311 is installed near the spray port of the auxiliary gas, the droplets DP sprayed from the capillary 301 may gradually accumulate on the surface of the light source 311. For example, a case is postulated where a high-concentration sample is measured, and at that time, the high-concentration sample is deposited on the light source 311. Next, when another sample is measured, if the charged droplet DP collides with the deposit, ionization occurs there. As a result, ions derived from the sample of the previous measurement are introduced into the mass spectrometer 5. As a result, there is a possibility that the measurement result of the preceding sample overlaps with the measurement result of the subsequent sample. Since there is a risk as described above, it is desirable that the light source 311 and the camera 2 are detached from the ion source 3 in the analysis mode.

FIGS. 13A and 13B are diagrams illustrating a structure of an ion source 3 according to the second embodiment. FIG. 13A is a cross-sectional view taken along line B-B illustrated in FIG. 13B, and FIG. 13B is a cross-sectional view taken along line A-A illustrated in FIG. 13A. In FIG. 13, the same components as those in FIG. 1 are denoted by the same reference numerals, and the description thereof will be omitted.

The housing 321 of the ion source 3 is provided with a transparent plate 332 as the scattered light information acquisition device installation portion in which the camera 2 may be installed, and a light source installation portion 331 in which the light source device 310 including the light source 311 can be installed.

The housing 321 of the ion source 3 has a cylindrical shape, and a place (light source installation portion 331) where the light source device 310 may be set is provided in a part thereof. Further, as illustrated in FIG. 13B, a transparent plate 332 made of a transparent member is provided on at least one surface of the housing 321, and the inside of the housing 321 is visually recognized. Considering that the auxiliary gas has a high temperature, heat-resistant glass or the like is preferably used as the transparent plate 332. In the example shown in FIGS. 13A and 13B, the transparent plate 332 is provided at a position facing the pores 503 of the mass spectrometer 5.

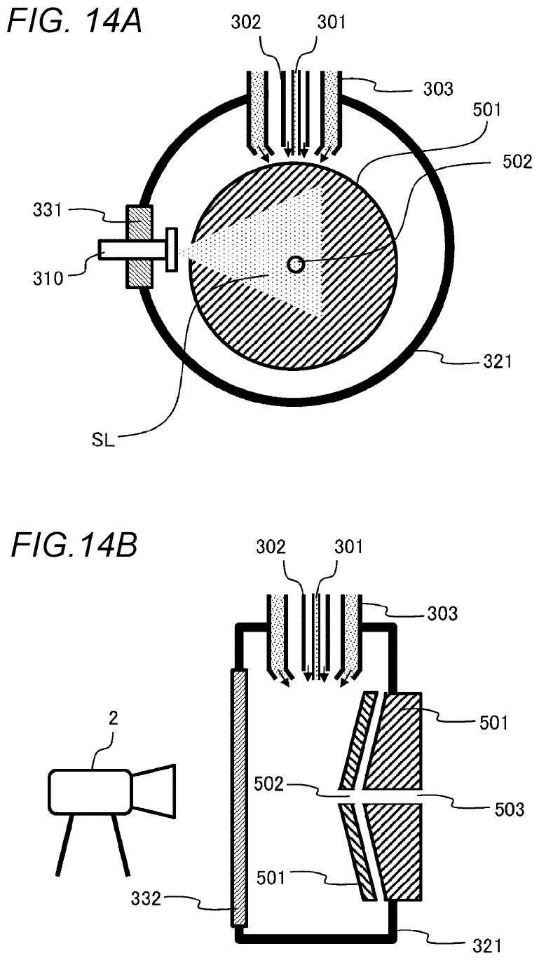

FIGS. 14A and 14B are diagrams illustrating a case where the light source device 310 is installed in the light source installation portion 331 of the housing 321 of FIGS. 13A and 13B, and the camera 2 is installed in front of the transparent plate 332. Note that FIG. 14A corresponds to FIG. 13A, and FIG. 14B corresponds to FIG. 13B. Furthermore, FIG. 1 is referred to as appropriate.

Note that, in the example illustrated in FIGS. 14A and 14B, a light source device 310 in which a light source 311 and a lens 312 (see FIG. 2) are integrated is installed. The droplet DP sprayed from the capillary 301 is irradiated with the laser sheet SL from a position orthogonal to a line connecting the camera 2 and the pores 503 of the mass spectrometer 5. Then, scattered light R (see FIG. 4A and the like) is captured by the camera 2 from a position facing the pores 503. Similarly to the first embodiment, the control unit 111 (or a human) changes the parameter. Then, the state of the scattered light R when the parameter changes is photographed by the camera 2, so that the measurement processing unit 113 acquires information of the scattered light R. Then, the determination processing unit 112 detects the failure of the channel system by comparing the acquired information on the scattered light R with the determination reference information 121. Note that a recording medium may be mounted on the camera 2, and analysis may be performed by the processing device 1 after data stored in the recording medium is transferred to the processing device 1. The analysis by the processing device 1 indicates that the processing illustrated in FIG. 12 is performed. Alternatively, as illustrated in FIG. 2, the camera 2 may be connected to the processing device 1, a captured image or video may be transmitted as it is to the processing device 1, and the processing device 1 may analyze the transmitted image or video.

As illustrated in FIGS. 13A to 14B, the housing 321 of the ion source 3 is provided with the light source installation portion 331 and the transparent plate 332. With such a configuration, the light source device 310 and the camera 2 are installed in the monitoring mode, and the light source device 310 and the camera 2 may be removed in the analysis mode. As a result, it is possible to prevent the light source 311 and the camera 2 from being contaminated, and it is possible to prevent the measurement accuracy in the analysis mode from deteriorating. In particular, since the place where the camera 2 is installed is formed of the transparent plate 332, installation and removal of the camera 2 are facilitated.

### Modification of Second Embodiment

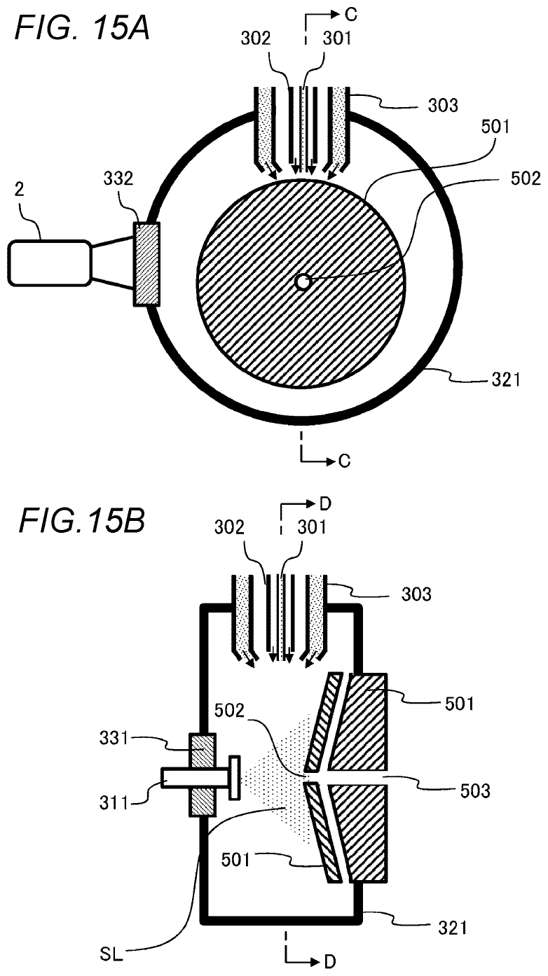

FIGS. 15A and 15B are diagrams illustrating a modification of the second embodiment.

In the example illustrated in FIGS. 15A and 15B, the positions of the camera 2 and the light source device 310 are replaced with the positions illustrated in FIGS. 14A and 14B. FIG. 15A is a cross-sectional view taken along line D-D illustrated in FIG. 15B, and FIG. 15B is a cross-sectional view taken along line C-C illustrated in FIG. 15A. In FIGS. 15A and 15B, the same components as those in FIGS. 14A and 14B are denoted by the same reference numerals, and description thereof is omitted.

In the example illustrated in FIGS. 15A and 15B, in the example illustrated in FIGS. 14A and 14B, the light source installation portion 331 is provided on the surface of the housing 321 on which the transparent plate 332 is installed. That is, the transparent plate 332 is provided in a direction orthogonal to the direction of the pores 503 of the mass spectrometer 5. Then, the light source device 310 is installed in the light source installation portion 331. Further, in the example illustrated in FIGS. 15A and 15B, in the example illustrated in FIGS. 14A and 14B, the transparent plate 332 is provided at a place where the light source installation portion 331 is installed. The camera 2 is installed on the transparent plate 332.

Note that the positions where the camera 2 and the light source 311 are installed are not necessarily limited to the locations illustrated in FIGS. 14A to 15B. As long as light (laser LA) can be applied to the droplet DP sprayed from the capillary 301 and the scattered light R can be detected, the positions where the camera 2 and the light source 311 are installed may be any positions. In addition, the light source 311 may be configured to be inserted into the housing 321 or may be configured to be irradiated from the outside of the housing 321. However, in a case where the laser LA light is emitted from the outside of the housing 321, the light source installation portion 331 is formed of a transparent member. Similarly, the camera 2 may be inserted into the housing 321 or an image may be captured from the outside of the transparent plate 332. Note that, in a case of a configuration in which the camera 2 is inserted into the housing 321, a hole (not illustrated) through which the camera 2 is inserted may be provided on the housing 321 instead of the transparent plate 332.

In the second embodiment, the light source 311 and the camera 2 are not installed in the analysis mode, that is, in the analysis mode, the light source 311 is removed from the housing 321, and the camera 2 is removed from the vicinity of the housing 321. Then, in the monitoring mode, the light source 311 is installed in the housing 321, and the camera 2 is installed in the vicinity of the housing 321. This is assumed to be operated by a person who maintains or repairs the liquid chromatography mass spectrometer CH. When the user of the liquid chromatography mass spectrometer CH suspects a failure in the channel system and calls a person from the manufacturer who maintains or repairs the liquid chromatography mass spectrometer CH, the person from the manufacturer brings the light source device 310, the camera 2, and the processing device 1. Then, the person from the manufacturer installs the light source device 310 and the camera 2 in the liquid chromatography mass spectrometer CH of the user at positions illustrated in FIGS. 14A and 14B or FIGS. 15A and 15B. Then, the person from the manufacturer changes the parameter manually or via the processing device 1, and analyzes the scattered light R derived from the droplet DP at that time. If the failure of the channel system is found by the method described in the first embodiment, the person from the manufacturer may immediately repair.

The present invention is not limited to the above-described embodiments, and encompasses various modifications. For example, the above-described embodiments have been described in detail for the sake of comprehensible explanation of the present invention, and are not necessarily limited to those provided with all the described configurations. Furthermore, a part of the configuration of one embodiment may be replaced with the configuration of another embodiment, and the configuration of another embodiment may be added to the configuration of one embodiment. In addition, with regard to a part of the configuration of each embodiment, addition of other configurations, deletion, and replacement are possible. In addition, in each embodiment, only the control lines and the information lines considered to be necessary for the description are shown, and not necessarily all the control lines and the information lines in the product are shown. In practice, it may be considered that almost all the configurations are connected to each other.

The present invention is not limited to the above-described embodiments, and encompasses various modifications. For example, the above-described embodiments have been described in detail for the sake of comprehensible explanation of the present invention, and are not necessarily limited to those provided with all the described configurations. Furthermore, a part of the configuration of one embodiment maybe replaced with the configuration of another embodiment, and the configuration of another embodiment may be added to the configuration of one embodiment. In addition, with regard to a part of the configuration of each embodiment, addition of other configurations, deletion, and replacement are possible.

In addition, some or all of the above-described configurations, functions, the control unit 111 to the measurement processing unit 113, the storage device 120, and the like may be realized by hardware, for example, by designing with an integrated circuit. In addition, as illustrated in FIG. 3, each of the above-described configurations, functions, and the like may be realized by software by a processor such as a CPU interpreting and executing a program for realizing each function. Information such as a program, a table, and a file for realizing each function may be stored in the memory 110, a recording device such as an SSD, or a recording medium such as an integrated circuit (IC) card, a secure digital (SD) card, or a digital versatile disc (DVD) in addition to the HD.

In addition, in each embodiment, only the control lines and the information lines considered to be necessary for the description are shown, and not necessarily all the control lines and the information lines in the product are shown. In practice, it may be considered that almost all the configurations are connected to each other.

What is claimed is:

1. A failure detection method comprising:
providing:
a light source configured to irradiate an inside of an electrospray ion source with light;
a scattered light information acquisition device configured to acquire scattered light information that is information of scattered light scattered by a droplet generated by electrospraying; and
a processing device configured to store, in a storage unit, determination reference information indicating a relationship between a parameter of a channel system of a liquid chromatography device in a normal state and the scattered light information,
by the processing device,
acquiring the scattered light information from the scattered light information acquisition device;
comparing acquired scattered light information with the determination reference information;
detecting a change in the scattered light relative to a value of the determination reference information based on the acquired scattered light information; and
determining a failure of a channel system in the liquid chromatography device based on the change in the scattered light.

2. The failure detection method according to claim 1, wherein
the processing device
acquires the scattered light information when a mixing ratio of a plurality of solvents introduced into the electrospray ion source changes.

3. The failure detection method according to claim 2, wherein
the processing device
acquires information with respect to a continuous change in the scattered light information when the mixing ratio of the plurality of solvents continuously changes.

4. The failure detection method according to claim 1, wherein
the processing device
acquires the scattered light information when a flow rate of a solvent introduced into the electrospray ion source changes.

5. The failure detection method according to claim 1, wherein
the scattered light information is intensity of the scattered light.

6. The failure detection method according to claim 1, wherein
a liquid chromatography mass spectrometer including the electrospray ion source
switches at least two modes;
the at least two modes includes an analysis mode during ion measurement and a monitoring mode during state monitoring, and
in the monitoring mode, at least one of a flow rate and a temperature in the monitoring mode is lowered relative to one in the analysis mode.

7. The failure detection method according to claim 1, wherein
a variation in the scattered light information caused by a droplet generated by electrospraying is used as an evaluation index for determining the failure.

8. The failure detection method according to claim 7, wherein
the scattered light information is intensity of the scattered light, and
when the intensity decreases in a pulsed manner, the processing device determines that air bubbles are contaminated in a solvent flowing through the channel system.

9. The failure detection method according to claim 7, wherein
the scattered light information is intensity of the scattered light, and
when the intensity decreases not in a pulsed manner, the processing device determines that liquid feeding is unstable due to a failure of a pump that feeds a solvent flowing through the channel system.

10. The failure detection method according to claim 1, wherein
parameters of the channel system are set by a plurality of values, and
the scattered light information acquisition device acquires the scattered light information at each of the plurality of values.

11. The failure detection method according to claim 1, wherein
the determination reference information stores at least information about a relationship between a flow rate of a solvent flowing through the channel system and the scattered light information, a relationship between a mixing ratio of the solvent in the channel system and the scattered light information, and a variation in information of the scattered light when no failure occurs in the channel system.

12. The failure detection method according to claim 1, wherein
a plurality of the channel systems are provided in which each of the channel systems includes a separation column,
the parameter for each of the plurality of channel systems is sequentially changed, and
the light irradiates from the channel system to the droplet generated in the electrospray ion source in which the parameter has been changed in the channel system.

13. The failure detection method according to claim 1, wherein
the light is a laser sheet.

14. A failure detection system comprising:
a light source configured to irradiate an inside of an electrospray ion source with light;
a scattered light information acquisition device configured to acquire scattered light information that is information of scattered light scattered by a droplet generated by electrospraying; and
a processing device that stores, in a storage unit, determination reference information indicating a relationship between a parameter of a channel system of a liquid chromatography device in a normal state and the scattered light information, wherein
the processing device includes:
a scattered light information acquisition unit configured to acquire the scattered light information from the scattered light information acquisition device; and
a determination processing unit configured to determine a failure of a channel system in the liquid chromatography device by detecting a change in acquired scattered light information relative to a value of the determination reference information by comparing the acquired scattered light information and the determination reference information.

15. An electrospray ion source comprising, in a housing:
a light source installation portion where a light source that irradiates an inside of the electrospray ion source with light is installed; and
installation portion where a scattered light information acquisition device that acquires scattered light information that is information of scattered light scattered by a droplet generated by electrospraying is installed.

16. The electrospray ion source according to claim 15, wherein
the scattered light information acquisition device installation portion includes a transparent member.

17. The electrospray ion source according to claim 15, wherein
the scattered light information acquisition device installation portion is provided in a position facing a pore of a mass spectrometer.

18. The electrospray ion source according to claim 15, wherein
the scattered light information acquisition device installation portion is provided in a direction orthogonal to a direction of a pore of a mass spectrometer.
